(19) United States
(12) Patent Application Publication
(10) Pub. No.: US 2021/0335575 A1
(43) Pub. Date: Oct. 28, 2021

(54) CERAMIC STRUCTURE, LOWER ELECTRODE, AND DRY ETCHING MACHINE

(71) Applicants: HKC CORPORATION LIMITED, Shenzhen (CN); CHONGQING HKC OPTOELECTRONICS TECHNOLOGY CO., LTD., Chongqing (CN)

(72) Inventor: Yi MENG, CHONGQING (CN)

(21) Appl. No.: 16/320,489

(22) PCT Filed: May 21, 2018
(86) PCT No.: PCT/CN2018/087648

§ 371 Date: Jan. 25, 2019

(30) Foreign Application Priority Data
Jan. 3, 2018 (CN) 20180007702.6

(51) Int. Cl. H01J 37/32

(52) U.S. Cl. CPC H01J 37/3255; H01J 37/32798; H01J 37/32568

(57) ABSTRACT

Disclosed are a ceramic structure, a lower electrode, and a dry etching machine. The ceramic structure includes at least two ceramic plates, and a clamping slot and a boss are arranged on one side of each ceramic plate close to a neighboring ceramic plate. In two neighboring ceramic plates, a boss of one ceramic plate is clamped into a clamping slot of the other ceramic plate, so that no through gap is generated between the two neighboring ceramic plates in a thickness direction.

### FIELD

The present disclosure relates to the field of etching machine technologies, and more particularly relates to a ceramic structure, a lower electrode, and a dry etching machine.

### BACKGROUND

An etching process is to chemically, physically, or simultaneously use chemical and physical methods to selectively remove a portion of a thin film layer that is not masked by a resist, thereby obtaining, on a film, a pattern completely the same as a resist film. The etching process is mainly divided into dry etching and wet etching. Dry etching mainly uses a reactive gas (such as plasma) for etching. Wet etching mainly uses a chemical reagent to chemically react with an etched material to perform etching.

A device that adopts the dry etching technology is referred to as a dry etching machine. The dry etching machine usually has a reaction chamber. An upper electrode connected to a power supply is arranged on an upper portion of the reaction chamber. A lower electrode corresponding to the upper electrode and grounded is arranged on a lower portion of the reaction chamber. The lower electrode is configured to receive and carry a to-be-etched product. In addition, air inlet and outlet pipes in communication with the reaction chamber are further arranged. The air inlet and outlet pipes are configured to import or export an reactive gas.

The lower electrode of the dry etching machine includes a substrate plate and a ceramic structure arranged on the substrate plate. The ceramic structure is configured to receive and carry a to-be-etched product and protect the substrate plate. The ceramic structure mostly includes a plurality of ceramic plates, and each ceramic plate is arranged on the substrate plate. After the plurality of ceramic plates is mounted, there is a gap between neighboring ceramic plates, resulting in a low degree of adhesion. During an etching operation, plasma may pass through the gaps into the substrate plate of the lower electrode, causing a tip discharge effect. Consequently, the lower electrode is damaged, causing the dry etching machine to be faulty and stop, affecting processing and production operations, and increasing corresponding maintenance and repair costs.

### SUMMARY

An objective of the present disclosure is to provide a ceramic structure, a lower electrode, and a dry etching machine.

According to one aspect of the present disclosure, a ceramic structure is provided. The ceramic structure includes at least two ceramic plates, where a clamping slot and a boss are arranged on one side of each ceramic plate close to a neighboring ceramic plate, in two neighboring ceramic plates, a boss of one ceramic plate is clamped into a clamping slot of the other ceramic plate, and the two neighboring ceramic plates are clamped together through engagement between the clamping slot and the boss.

According to another aspect of the present disclosure, a lower electrode including the foregoing ceramic structure is provided.

According to still another aspect of the present disclosure, a dry etching machine including the foregoing lower electrode is provided.

The clamping slot and the boss on one side of the ceramic plate are arranged in engagement, so that no through gap is generated between the two neighboring ceramic plates in a thickness direction, thereby effectively preventing plasma from passing through gaps between the ceramic plates into a substrate plate of the lower electrode during an etching operation, and preventing a tip discharge effect from occurring, thereby preventing the lower electrode from being damaged and causing the dry etching machine to be faulty and stop.

### BRIEF DESCRIPTION OF THE DRAWINGS

FIG. 1 is a schematic diagram of a ceramic structure according to the present disclosure;

FIG. 2 is a schematic structural diagram of a ceramic plate included in the ceramic structure shown in FIG. 1;

FIG. 3 is a schematic diagram of another ceramic structure according to the present disclosure;

FIG. 4 is a schematic diagram of still another ceramic structure according to the present disclosure;

FIG. 5 is a schematic diagram of still another ceramic structure according to the present disclosure;

FIG. 6 is a schematic diagram of still another ceramic structure according to the present disclosure;

FIG. 7 is a schematic structural diagram of a lower electrode according to the present disclosure; and

FIG. 8 is a schematic diagram of a dry etching machine according to the present disclosure.

In the figures:

10. Ceramic structure; 11. Ceramic plate; 111. Clamping slot; 112. Boss;

20. Substrate plate;

100. Lower electrode; 200. Reaction chamber; 300. Upper electrode; 400. Air inlet pipe; 500. Air outlet pipe.

### DETAILED DESCRIPTION OF THE INVENTION

The following describes in detail embodiments of the present disclosure. Examples of the embodiments are shown in the accompanying drawings, where reference signs that are the same or similar from beginning to end represent same or similar components or components that have same or similar functions. The following embodiments described with reference to the accompanying drawings are exemplary, and are intended to explain the present disclosure and cannot be construed as a limitation on the present disclosure.

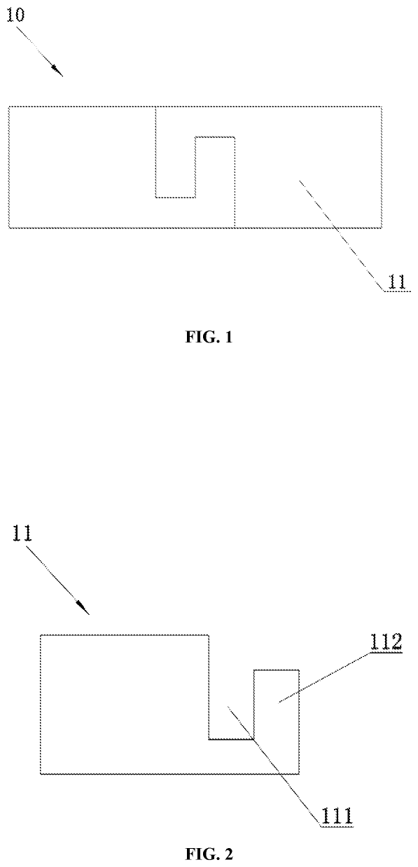

As shown in FIG. 1 and FIG. 2, the present disclosure provides a ceramic structure 10, which may be used as one part of a lower electrode of a dry etching machine. The ceramic structure 10 includes at least two ceramic plates 11. A clamping slot 111 and a boss 112 are arranged on one side of each ceramic plate 11 close to a neighboring ceramic plate 11. In two neighboring ceramic plates 11, a boss 112 of one ceramic plate 11 is clamped into a clamping slot 111 of the other ceramic plate 11. The two neighboring ceramic plates 11 are clamped together through engagement between the clamping slot 111 and the boss 112, so that no through gap is generated between the two neighboring ceramic plates 11 in a thickness direction. In the present disclosure, the clamping slot 111 and the boss 112 on one side of the ceramic plate 11 are arranged in engagement, so that no through gap is generated between the two neighboring ceramic plates 11 in the thickness direction, thereby effectively preventing plasma from passing through gaps between the ceramic plates 11 into a substrate plate 20 of the lower electrode during an etching operation, and preventing a tip discharge effect from occurring, thereby preventing the lower electrode from being damaged and causing the dry etching machine to be faulty and stop.

In an embodiment, the clamping slot 111 and the boss 112 are both obtained through cutting processing of the ceramic plate 11. The cutting process is adopted, the processing is convenient, and preparation costs are low.

In this embodiment, upper surfaces of the two ceramic plates 11 that are clamped together are in a same plane, so that a to-be-etched product placed on the ceramic structure 10 of the present disclosure is more safe and reliable.

In an embodiment, the clamping slot 111 and the boss 112 are obliquely arranged.

In another embodiment, a depth opening direction of the clamping slot 111 and a protrusion direction of the boss 112 are both perpendicular to the ceramic plates 11, so that each ceramic plate 11 can be independently mounted on the substrate plate 20 of the lower electrode 100.

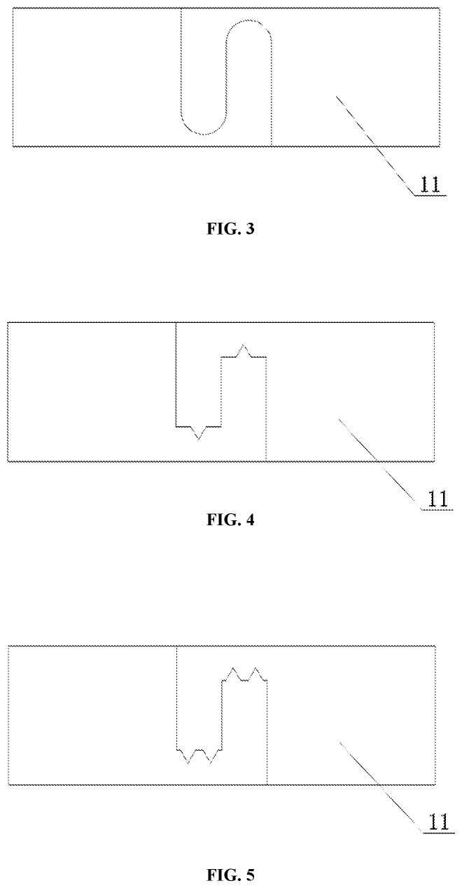

In another embodiment, as shown in FIG. 3, a slot bottom of the clamping slot 111 is a recessed arc-shaped slot bottom, an end portion of the boss 112 is a convex arc-shaped terminal, and the arc-shaped slot bottom and the arc-shaped terminal are arranged in engagement. The arrangement of the arc-shaped slot bottom and the arc-shaped terminal through arc-shaped guiding makes the clamping and alignment between the neighboring ceramic plates 11 more accurate, thereby increasing a contact area, and making connection more reliable.

In another embodiment, as shown in FIG. 4, a cone-shaped slot is arranged in a slot bottom of the clamping slot 111, a cone-shaped convex head is arranged on an end portion of the boss 112, and the cone-shaped slot and the cone-shaped convex head are arranged in engagement. The cone-shaped slot and the cone-shaped convex head are guided by cone-shaped side surfaces, so that the clamping and alignment between the neighboring ceramic plates 11 are more accurate.

In another embodiment, as shown in FIG. 5, a plurality of cone-shaped slots in a slot bottom of the clamping slot 111 and a plurality of cone-shaped convex heads on an end portion of the boss 112 are arranged in pairs. The plurality of cone-shaped slots and the plurality of cone-shaped convex heads make clamping between the clamping slot 111 and the boss 112 more reliable.

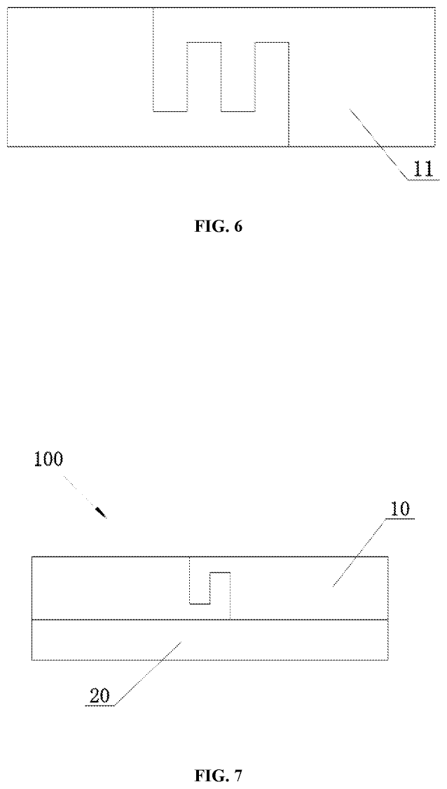

In another embodiment, as shown in FIG. 6, a plurality of clamping slots 111 and a plurality of bosses 112 are arranged on one side of the ceramic plate 11, and two neighboring ceramic plates 11 are clamped together through engagement between the plurality of clamping slots 111 and the plurality of bosses 112. In the foregoing arrangement, clamping between neighboring ceramic plates 11 is more reliable. As shown in FIG. 7, the present disclosure further provides a lower electrode 100, including the foregoing ceramic structure 10. The lower electrode 100 of the present disclosure further includes a substrate plate 20. The ceramic plates 11 of the ceramic structure 10 of the present disclosure are separately mounted on the substrate plate 20 and are clamped to each other. In the lower electrode 100 of the present disclosure, the clamping slot 111 and the boss 112 on one side of the ceramic plate 11 are arranged in engagement, so that no through gap is generated between the two neighboring ceramic plates 11 in a thickness direction, thereby effectively preventing plasma from passing through gaps between the ceramic plates 11 into the substrate plate 20 of the lower electrode 100 during an etching operation, and preventing a tip discharge effect from occurring, thereby preventing the lower electrode 100 from being damaged and causing the dry etching machine to be faulty and stop.

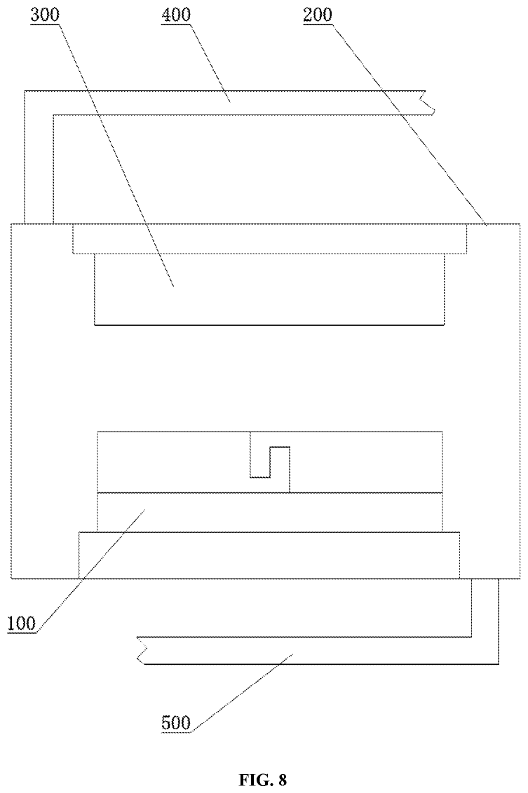

As shown in FIG. 8, the present disclosure further provides a dry etching machine, including the foregoing lower electrode 100. The dry etching machine of the present disclosure further includes a reaction chamber 200, an air inlet pipe 400 in communication with the reaction chamber 200, an air outlet pipe 500 in communication with the reaction chamber 200, the lower electrode 100 arranged inside the reaction chamber 200, and an upper electrode 300 corresponding to the lower electrode 100. The upper electrode 300 is arranged on an upper side of and inside the reaction chamber 200 and is connected to a power supply. The lower electrode 100 of the present disclosure is grounded through wires, and configured to receive and carry a to-be-etched product. The air inlet pipe 400 and the air outlet pipe 500 are configured to respectively import or export an etching reactive gas. In the dry etching machine of the present disclosure, the clamping slot 111 and the boss 112 on one side of the ceramic plate 11 are arranged in engagement, so that no through gap is generated between the two neighboring ceramic plates 11 in the thickness direction, thereby effectively preventing plasma from passing through gaps between the ceramic plates 11 into the substrate plate 20 of the lower electrode 100 during an etching operation, and preventing a tip discharge effect from occurring, thereby preventing the lower electrode 100 from being damaged and causing the dry etching machine to be faulty and stop.

Apparently, the foregoing embodiments of the present disclosure are merely intended to clearly describe examples in the present disclosure and not to limit implementations of the present disclosure. Other variations or modifications in other different forms may also be made by a person of ordinary skill in the art based on the foregoing descriptions. It is not necessary and possible to exhaust all implementations herein. Any modifications, equivalent replacements, and improvements made within the spirit and principle of the present disclosure shall fall within the protection scope of the claims of the present disclosure.

1. A ceramic structure, comprising at least two ceramic plates, wherein a clamping slot and a boss are arranged on one side of each ceramic plate close to a neighboring ceramic plate, in two neighboring ceramic plates, a boss of one ceramic plate is clamped into a clamping slot of the other ceramic plate, and the two neighboring ceramic plates are clamped together through engagement between the clamping slot and the boss.

2. The ceramic structure according to claim 1, wherein the clamping slot and the boss are both obtained through cutting processing.

3. The ceramic structure according to claim 1, wherein upper surfaces of the two ceramic plates that are clamped together are in a same plane.

4. The ceramic structure according to claim 3, wherein a depth opening direction of the clamping slot and a protrusion direction of the boss are both perpendicular to the ceramic plates.

5. The ceramic structure according to claim 4, wherein a slot bottom of the clamping slot is a recessed arc-shaped slot bottom, an end portion of the boss is a convex arc-shaped terminal, and the arc-shaped slot bottom matches the arc-shaped terminal.

6. The ceramic structure according to claim 4, wherein a cone-shaped slot is arranged in a slot bottom of the clamping slot, a cone-shaped convex head is arranged on an end portion of the boss, and the cone-shaped slot matches the cone-shaped convex head.

7. The ceramic structure according to claim 4, wherein the number of cone-shaped slots in a slot bottom of the clamping slot is greater than or equal to 2, the number of cone-shaped convex heads on an end portion of the boss is greater than or equal to 2, and the cone-shaped slots and the cone-shaped convex heads are arranged in pairs.

8. The ceramic structure according to claim 1, wherein the number of clamping slots of the ceramic plates is greater than or equal to 2, the number of bosses is greater than or equal to 2 and is the same as the number of clamping slots, and each boss of the ceramic plate is clamped into the corresponding clamping slot of the other ceramic plate.

9. A lower electrode, comprising a ceramic structure, wherein
the ceramic structure comprises at least two ceramic plates, wherein a clamping slot and a boss are arranged on one side of each ceramic plate close to a neighboring ceramic plate, in two neighboring ceramic plates, a boss of one ceramic plate is clamped into a clamping slot of the other ceramic plate, and the two neighboring ceramic plates are clamped together through engagement between the clamping slot and the boss.

10. The lower electrode according to claim 9, wherein the clamping slot and the boss are obtained through cutting processing.

11. The lower electrode according to claim 10, wherein upper surfaces of the two ceramic plates that are clamped together are in a same plane.

12. The lower electrode according to claim 11, wherein a depth opening direction of the clamping slot and a protrusion direction of the boss are both perpendicular to the ceramic plates.

13. The lower electrode according to claim 12, wherein a slot bottom of the clamping slot is a recessed arc-shaped slot bottom, an end portion of the boss is a convex arc-shaped terminal, and the arc-shaped slot bottom matches the arc-shaped terminal.

14. The lower electrode according to claim 12, wherein a cone-shaped slot is arranged in a slot bottom of the clamping slot, a cone-shaped convex head is arranged on an end portion of the boss, and the cone-shaped slot and the cone-shaped convex head are arranged in engagement.

15. The lower electrode according to claim 14, wherein the number of cone-shaped slots in a slot bottom of the clamping slot is greater than or equal to 2, the number of cone-shaped convex heads on an end portion of the boss is greater than or equal to 2, and the cone-shaped slots and the cone-shaped convex heads are arranged in pairs.

16. The lower electrode according to claim 9, wherein the number of clamping slots of the ceramic plates is greater than or equal to 2, the number of bosses is greater than or equal to 2, and each boss of the ceramic plate is clamped into the corresponding clamping slot of the other ceramic plate.

17. A dry etching machine, comprising a lower electrode, wherein
the lower electrode comprises a ceramic structure, the ceramic structure comprises at least two ceramic plates, wherein a clamping slot and a boss are arranged on one side of each ceramic plate close to a neighboring ceramic plate, in two neighboring ceramic plates, a boss of one ceramic plate is clamped into a clamping slot of the other ceramic plate, and the two neighboring ceramic plates are clamped together through engagement between the clamping slot and the boss.

18. The dry etching machine according to claim 17, wherein the clamping slot and the boss are obtained through cutting processing.

19. The dry etching machine according to claim 18, wherein upper surfaces of the two ceramic plates that are clamped together are in a same plane.

20. The dry etching machine according to claim 19, wherein a depth opening direction of the clamping slot and a protrusion direction of the boss are both perpendicular to the ceramic plates.
